(19) United States
(12) Patent Application Publication
(10) Pub. No.: US 2016/0056088 A1
(43) Pub. Date: Feb. 25, 2016

(54) Cold Plate, Device Comprising a Cold Plate and Method for Fabricating a Cold Plate

(71) Applicant: Infineon Technologies AG, Neubiberg (DE)

(72) Inventors: Andre Uhlemann, Dortmund (DE); Christoph Koch, Salzkotten (DE); Alexander Schwarz, Soest (DE)

(21) Appl. No.: 14/826,629

(22) Filed: Aug. 14, 2015

(30) Foreign Application Priority Data
Aug. 19, 2014 (DE) 102014111786.7

(51) Int. Cl. H01L 23/473; H01L 23/492; H01L 23/498; B23K 9/00; B23K 1/00; B23K 20/12; B23K 20/22; B23K 26/21; B23K 26/323; H01L 23/373; B23K 9/23

(52) U.S. Cl. CPC H01L 23/473; H01L 23/3736; H01L 23/4924; H01L 23/49811; B23K 9/0026; B23K 9/232; B23K 20/129; B23K 20/22; B23K 26/21; B23K 26/323; B23K 1/00; B23K 2203/18

(57) ABSTRACT

A cold plate includes a single piece member and a channel. A top side of the channel is open. A bottom side of the channel opposite the top side has an inlet and an outlet.

### PRIORITY CLAIM

This application claims priority to German Patent Application No. 10 2014 111 786.7 filed on 19 Aug. 2014, the content of said German application incorporated herein by reference in its entirety.

### TECHNICAL FIELD

This invention relates to cold plates, devices comprising a cold plate and methods for fabricating cold plates.

### BACKGROUND

Semiconductor modules comprising at least one semiconductor chip, in particular a power semiconductor chip, may produce heat during operation. It may be necessary to provide a means for dissipating such heat as otherwise the semiconductor module may overheat. Cold plates comprising a channel for a cooling fluid may be used as such a means. The particular design of the cold plate may influence a thermal resistance between the semiconductor chip and the cooling fluid. It may be desirable to reduce the thermal resistance in order to improve a cooling of the semiconductor module. Furthermore, the particular design of the cold plate may influence its cost of manufacturing. For these and other reasons there is a need for the present invention.

### SUMMARY

According to an embodiment of a device, the device comprises a semiconductor module and a cold plate. The cold plate is comprised of a single piece member.

According to an embodiment of a cold plate, the cold plate comprises a channel. The cold plate is comprised of a single piece member. A top side of the channel is open. A bottom side of the channel opposite the top side comprises an inlet and an outlet.

According to an embodiment of a method for fabricating a device, the method comprises: providing a substrate configured for coupling a semiconductor chip to the substrate; providing a cold plate comprising a channel; and coupling the cold plate to the substrate. The cold plate is comprised of a single piece member.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference numerals may designate corresponding similar parts.

FIG. 1A shows a cut through an example of a standard cold plate.

FIG. 1B shows a cut through a device comprising a semiconductor module and the cold plate of FIG. 1A.

FIG. 2A shows a cut through a cold plate according to an example.

FIG. 2B shows a cut through a device comprising a semiconductor module and the cold plate of FIG. 2A.

FIG. 3 shows a bottom up view of the cold plate of FIG. 2A.

FIG. 4A shows a perspective view of the top side of a further example of a cold plate and a substrate.

FIG. 4B shows a perspective view of the bottom side of the cold plate of FIG. 4B.

FIG. 5A shows a cut through another example of a cold plate.

FIG. 5B shows a zoomed in perspective view of details of a channel comprised in the cold plate of FIG. 5A.

FIG. 6 shows a flow diagram of an example of a method for fabricating a cold plate.

FIG. 7 shows a flow diagram of an example of a method for fabricating a device comprising a cold plate.

FIG. 8 shows a perspective view of an example of a cold plate and a substrate.

FIG. 9 shows a perspective view of an example of a semiconductor device.

### DETAILED DESCRIPTION

In the following detailed description, reference is made to the accompanying drawings which illustrate specific aspects in which the disclosure may be practiced. In this regard, directional terminology, such as “top”, “bottom”, “front”, “back”, etc., may be used with reference to the orientation of the figures being described. Since components of described devices maybe positioned in a number of different orientations, the directional terminology maybe used for purposes of illustration and is in no way limiting.

The various aspects summarized may be embodied in various forms. The following description shows by way of illustration various combinations and configurations in which the aspects may be practiced. It is understood that the described aspects and/or examples are merely examples and that other aspects and/or examples may be utilized and structural and functional modifications may be made without departing from the concept of the present disclosure. The following detailed description is therefore not to be taken in a limiting sense, and the concept of the present disclosure is defined by the appended claims. In addition, while a particular feature or aspect of an example may be disclosed with respect to only one of several implementations, such feature or aspect may be combined with one or more other features or aspects of the other implementations as it may be desired and advantageous for any given or particular application.

It is to be appreciated that features and/or elements depicted herein may be illustrated with particular dimensions relative to each other for purposes of simplicity and ease of understanding. Actual dimensions of the features and/or elements may differ from that illustrated herein.

As employed in this specification, the terms “connected”, “coupled”, “electrically connected” and/or “electrically coupled” are not meant to mean that the elements must be directly coupled together. Intervening elements maybe provided between the “connected”, “coupled”, “electrically connected” and/or “electrically coupled” elements.

The words “over” and “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

To the extent that the terms “include”, “have”, “with” or other variants thereof are used in either the detailed description or the claims, such terms are intended to be inclusive in a manner similar to the term “comprise”. Also, the term “exemplary” is merely meant as an example, rather than the best or optimal.

Semiconductor modules, cold plates, devices comprising semiconductor modules and cold plates and methods for manufacturing the cold plates and devices are described herein. Comments made in connection with a described device or cold plate may also hold true for a corresponding method and vice versa. For example, when a specific component of an device or cold plate is described, a corresponding method for manufacturing the device or cold plate may include an act of providing the component in a suitable manner, even when such an act is not explicitly described or illustrated in the figures. A sequential order of acts of a described method may be exchanged if technically possible. At least two acts of a method may be performed at least partly at the same time. In general, the features of the various exemplary aspects described herein may be combined with each other, unless specifically noted otherwise.

Semiconductor modules in accordance with the disclosure may include one or more semiconductor chips. The semiconductor chips may be of different types and may be manufactured by different technologies. For example, the semiconductor chips may include integrated electrical, electro-optical or electro-mechanical circuits or passives. The integrated circuits may be designed as logic integrated circuits, analog integrated circuits, mixed signal integrated circuits, power integrated circuits, memory circuits, integrated passives, micro-electro mechanical systems, etc. The semiconductor chips may be manufactured from any appropriate semiconductor material, for example at least one of Si, SiC, SiGe, GaAs, GaN, etc. Furthermore, the semiconductor chips may contain inorganic and/or organic materials that are not semiconductors, for example at least one of insulators, plastics, metals, etc. The semiconductor chips may be packaged or unpackaged.

In particular, one or more of the semiconductor chips may include a power semiconductor. Power semiconductor chips may have a vertical structure, i.e. the semiconductor chips may be fabricated such that electric currents may flow in a direction perpendicular to the main faces of the semiconductor chips. A semiconductor chip having a vertical structure may have electrodes on its two main faces, i.e. on its top side and bottom side. In particular, power semiconductor chips may have a vertical structure and may have load electrodes on both main faces. For example, the vertical power semiconductor chips maybe configured as power MOSFETs (Metal Oxide Semiconductor Field Effect Transistors), IGBTs (Insulated Gate Bipolar Transistors), JFETs (Junction Gate Field Effect Transistors), super junction devices, power bipolar transistors, etc. The source electrode and gate electrode of a power MOSFET may be situated on one face, while the drain electrode of the power MOSFET may be arranged on the other face. In addition, the devices described herein may include integrated circuits to control the integrated circuits of the power semiconductor chips.

The semiconductor chips may include contact pads (or contact terminals) which may allow electrical contact to be made with integrated circuits included in the semiconductor chips. For the case of a power semiconductor chip, a contact pad may correspond to a gate electrode, a source electrode or a drain electrode. The contact pads may include one or more metal and/or metal alloy layers that may be applied to the semiconductor material. The metal layers may be manufactured with any desired geometric shape and any desired material composition.

Semiconductor modules in accordance with the disclosure may include a carrier or substrate. The carrier may be configured to provide electrical interconnections between electronic components and/or semiconductor chips arranged over the carrier such that an electronic circuit may be formed. In this regard, the carrier may act similar to a Printed Circuit Board (PCB). The materials of the carrier may be chosen to support a cooling of electronic components arranged over the carrier. The carrier may be configured to carry high currents and provide high voltage isolation, for example up to several thousand volts. The carrier may further be configured to operate at temperatures up to 150° C., in particular up to 200° C. or even higher. Since the carrier may particularly be employed in power electronics, it may also be referred to as “power electronic substrate” or “power electronic carrier”.

The carrier may include an electrically insulating core that may include at least one of a ceramic material and a plastic material. For example, the electrically insulating core may include at least one of Al₂O₃, AlN, Si₃N₄, etc. The carrier may have one or more main surfaces, wherein at least one main surface may be formed such that one or more semiconductor chips may be arranged thereupon. In particular, the substrate may include a first main surface and a second main surface arranged opposite to the first main surface. The first main surface and the second main surface may be substantially parallel to each other. The electrically insulating core may have a thickness between about 50 μm (micrometer) and about 1.6 millimeter.

Semiconductor modules in accordance with the disclosure may include a first electrically conductive material that may be arranged over (or on) a first main surface of the carrier. In addition, the semiconductor module may include a second electrically conductive material that may be arranged over (or on) a second main surface of the carrier opposite to the first main surface. The first and second electrically conductive materials may comprise different metal compositions. The term “carrier” as used herein may refer to the electrically insulating core, but may also refer to the electrically insulating core including the electrically conductive material arranged over the core. The electrically conductive material may include at least one of a metal and a metal alloy, for example copper and/or a copper alloy, or aluminum or an aluminum alloy. The electrically conductive material maybe shaped or structured in order to provide electrical interconnections between electronic components arranged over the carrier. In this regard, the electrically conductive material may include electrically conductive lines, layers, surfaces, zones, etc. For example, the electrically conductive material may have a thickness between about 0.1 millimeter and about 0.5 millimeter.

In one example, the carrier may correspond to (or may include) a Direct Copper Bond (DCB) or Direct Bond Copper (DBC) substrate. A DCB substrate may include a ceramic core and a sheet or layer of copper arranged over (or on) one or both main surfaces of the ceramic core. The ceramic material may include at least one of alumina (Al₂O₃), that may have a thermal conductivity from about 24 W/mK to about 28 W/mK, aluminum nitride (AlN), that may have a thermal conductivity greater than about 150 W/mK, beryllium oxide (BeO), etc. Compared to pure copper, the carrier may have a coefficient of thermal expansion similar or equal to that of silicon.

For example, the copper may be bonded to the ceramic material using a high-temperature bonding process. For example, a high-temperature oxidation process may be used. Here, the copper and the ceramic core may be heated to a controlled temperature in an atmosphere of nitrogen containing about 30 ppm of oxygen. Under these conditions, a copper-oxygen eutectic may form which may bond both to copper and oxides that may be used as substrate core. The copper layers arranged over the ceramic core may be pre-formed prior to firing or may be chemically etched using a printed circuit board technology to form an electrical circuit. A related technique may employ a seed layer, photo imaging and additional copper plating in order to allow for electrically conductive lines and through-vias to connect a front main surface and a back main surface of the substrate.

In a further example, the carrier may correspond to (or may include) an Active Metal Brazed (AMB) substrate. In AMB technology, metal layers may be attached to ceramic plates. In particular, a metal foil may be soldered to a ceramic core using a solder paste at high temperatures from about 800° C. to about 1000° C.

In yet a further example, the carrier may correspond to (or may include) an Insulated Metal Substrate (IMS). An IMS may include a metal plate covered by a thin layer of dielectric and a layer of copper. For example, the metal plate may be made of or may include at least one of aluminum and copper while the dielectric may be an epoxy-based layer. The copper layer may have a thickness from about 35 μm (micrometer) to about 200 μm (micrometer) or even higher. The dielectric may e.g. be FR-4-based and may have a thickness of about 100 μm (micrometer).

In yet a further example, the carrier or substrate may correspond to (or may include) a Direct Aluminum Bond (DAB) substrate, or a Direct Copper Aluminum Bond (DCAB) substrate. A DCAB substrate may comprise at least one aluminum layer and at least one copper layer arranged on the at least one aluminum layer.

Semiconductor modules in accordance with the disclosure may include an encapsulation material that may cover one or more components of the module. For example, the encapsulation material may at least partly encapsulate the carrier. The encapsulation material may be electrically insulating and may form an encapsulation body or encapsulant. The encapsulation material may include a thermoset, a thermoplastic or hybrid material, a mold compound, a laminate (prepreg), a silicone gel, etc. Various techniques may be used to encapsulate the components with the encapsulation material, for example at least one of compression molding, injection molding, powder molding, liquid molding, lamination, etc.

Semiconductor modules in accordance with the disclosure may include one or more electrically conductive elements. In one example, an electrically conductive element may provide an electrical connection to a semiconductor chip of the device. For example, the electrically conductive element may be connected to an encapsulated semiconductor chip and may protrude out of the encapsulation material. Hence, it may be possible to electrically contact the encapsulated semiconductor chip from outside of the encapsulation material via the electrically conductive element. In a further example, an electrically conductive element may provide an electrical connection between components of the device, for example between two semiconductor chips. A contact between the electrically conductive element and e.g. a contact pad of a semiconductor chip may be established by any appropriate technique. In an example, the electrically conductive element may be soldered to another component, for example by employing a diffusion soldering process.

In one example, the electrically conductive element may include one or more clips (or contact clips). The shape of a clip is not necessarily limited to a specific size or a specific geometric shape. The clip may be fabricated by at least one of stamping, punching, pressing, cutting, sawing, milling, and any other appropriate technique. For example, it may be fabricated from metals and/or metal alloys, in particular at least one of copper, copper alloys, nickel, iron nickel, aluminum, aluminum alloys, steel, stainless steel, etc. In a further example, the electrically conductive element may include one or more wires (or bond wires or bonding wires). The wire may include a metal or a metal alloy, in particular gold, aluminum, copper, or one or more of their alloys. In addition, the wire may or may not include a coating. The wire may have a thickness from about 15 μm (micrometer) to about 1000 μm (micrometer), and more particular a thickness of about 50 μm (micrometer) to about 500 μm (micrometer).

In the following, various examples of a cold plate are described. A cold plate may comprise a metal plate, wherein the metal plate may comprise one or more of aluminum, copper, an aluminum alloy, and a copper alloy. Manufacturing a cold plate may comprise one or more of stamping, rolling, and pressing a metal plate. A cold plate may be comprised of a single piece member, in particular a single piece continuous metal plate. A cold plate may have any suitable form or shape, in particular any form or shape suitable for coupling the cold plate to a substrate configured to be coupled to a semiconductor chip, in particular a power semiconductor chip.

In the following, examples of cold plates comprising a single channel are described in detail. In further examples, the cold plates may also have more than one channel.

Fabricating a cold plate from a single piece member, in particular a rolled, stamped, and/or pressed metal plate may be cost efficient compared to other methods of fabricating a cold plate.

A cold plate may comprise a channel configured for a cooling fluid to flow through the channel. The cooling fluid may comprise one or more of water and oil. The channel of the cold plate may be partially open, meaning that the cold plate may be configured in a way such that a side wall of the channel is “missing”. The partially open channel may be sealed by coupling the cold plate to a substrate like a substrate of a semiconductor module, such that at least apart of a main surface of the substrate forms the “missing” wall of the channel. Due to this coupling the cold plates described here may be called “integrated heat sinks” of the semiconductor modules. The partially open channel may be sealed without having to use a sealing ring. Instead, a tight seal may be obtained by coupling the cold plate to the substrate as outlined in the following.

A cold plate may be coupled to a semiconductor module using various techniques. A coupling may comprise one or more of sintering, soldering, welding, and active metal brazing. In particular, a cold plate may be coupled to a semiconductor module in such a way that no thermal grease layer is arranged between a semiconductor chip of the semiconductor module and the cold plate. Such a design may help to reduce the thermal resistance between the semiconductor chip and the cold plate.

In the following figures, examples of cold plates, semiconductor modules and devices comprising cold plates and semiconductor modules are shown. Corresponding parts in the individual figures are denoted by reference numbers whose last two digits are identical.

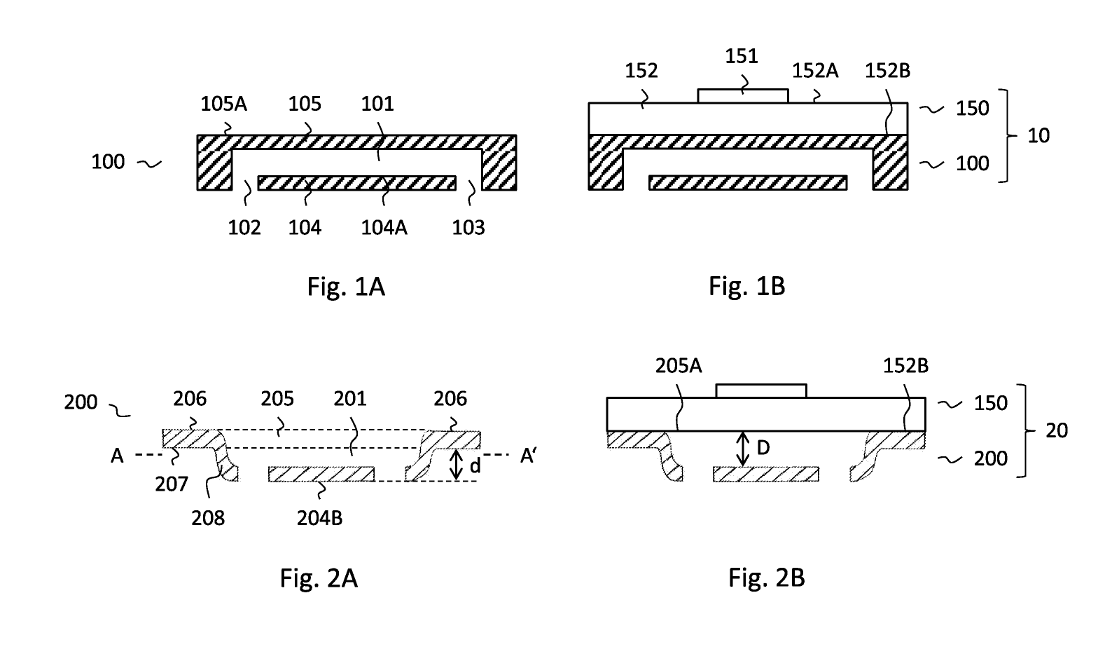

FIG. 1A shows a cut through an example of a standard cold plate 100. Cold plate 100 comprises a channel 101, a first opening 102 and a second opening 103. First opening 102 may be an inlet configured to let a cooling fluid flow into channel 101, and second opening 103 may be an outlet configured to let the cooling fluid flow out of the channel 101. First and second openings 102 and 103 are arranged in a bottom part 104 of the cold plate 100 opposite a top part 105. Reference number 105A denotes a top side and reference number 104A denotes a bottom side of an inner surface of the channel 101.

FIG. 1B shows a semiconductor module 150 comprising at least a first semiconductor chip 151 and a carrier or substrate 152. Semiconductor chip 151 is coupled to a first main surface 152A of substrate 152. A second main surface 152B of substrate 152 opposite the first main surface 152A is configured to be coupled to a cold plate, for example cold plate 100. FIG. 1B shows a cold plate 100 coupled to semiconductor module 150 such that cold plate top part 105 faces the second main surface 152B of substrate 152. Coupled semiconductor module 150 and cold plate 100 form a device 10.

Heat generated in semiconductor module 150, for example in semiconductor chip 151, may be transferred via substrate 152 and cold plate top part 105 to a cooling fluid flowing through channel 101. Thereby, cold plate 100 may act as a cooling system of device 10 for dissipating heat generated in semiconductor module 150.

FIG. 2A shows a cut through another example of a cold plate 200. Cold plate 200 may be partially similar to cold plate 100. However, a channel 201 of cold plate 200 is partially open. “Partially open” means that channel 201 has no top cover like top part 105 of cold plate 100. In FIG. 2A the open top of channel 201 is depicted by dashed lines 205. Cold plate 100 may be fabricated using a method for fabricating a cold plate like method 600 described further below.

FIG. 2B shows an example of a device 20 comprising semiconductor module 150 and cold plate 200 coupled to semiconductor module 150 such that open top 205 of channel 201 faces second main surface 152B of substrate 152. In device 20, second main surface 152B acts as a top cover which seals channel 201, meaning that cold plate top surface 206 is coupled to second main surface 152B in such a way that no cooling fluid leaks out of channel 201. Since at least a part of second main surface 152B forms the “missing” top side inner surface 205A of channel 201, semiconductor module 150 maybe in direct contact with the cooling fluid inside of channel 201.

Coupling cold plate 200 to substrate 152 may comprise one or more of sintering, welding soldering, active metal brazing and any other suitable coupling technique. Suitable welding techniques may particularly comprise, among others, laser welding, arc welding, and friction welding.

Note that in some examples of a device similar to device 20 one or more material layers configured to couple a semiconductor module like semiconductor module 150 to a cold plate like cold plate 200 may be arranged on second main surface 152B. The one or more material layers may for example comprise a solder layer. In this case, the outermost of the one or more material layers forms top side inner surface 205A of channel 201 and is in direct contact with the cooling fluid inside channel 201.

Alternatively, in some examples of a device similar to device 20 one or more material layers configured to couple a semiconductor module like semiconductor module 150 to a cold plate like cold plate 200 may be arranged on cold plate top surface 206 (see FIG. 2A). In this case, the one or more material layers are not arranged over the open top 205, and therefore second main surface 152B of substrate 152 is in direct contact with the cooling fluid inside the channel.

Channel 201 may have any desirable depth D and may in particular have a depth D in the range of 1 mm to 6 mm. Depth D may be uniform along channel 201 from inlet to outlet or may vary along channel 201.

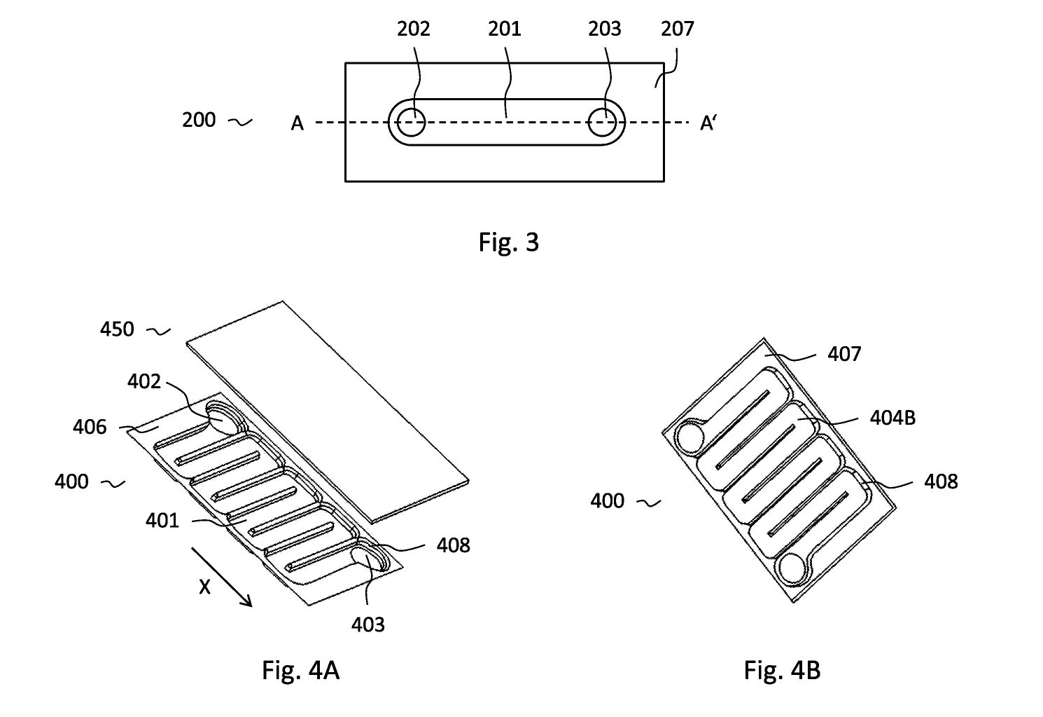

FIG. 3 shows a bottom up view of cold plate 200. Dashed line A-A′ depicts the cut through cold plate 200 shown in FIGS. 2A and 2B. FIG. 3 shows channel 201 to be of straight shape. Other channel shapes, like for example a meandering shape, may also be used in cold plate 200 or a cold plate similar thereto. The specific shape of channel 201 may depend on the requirements of the specific application.

FIG. 4A shows a perspective view of the top side of a further example of a cold plate 400 and the top side of a component 450. Cold plate 400 may be considered to be identical to cold plate 200 except for the fact that channel 401 of cold plate 400 has a meandering shape. Here “meandering shape” means that channel 401 meanders through cold plate 400 perpendicular to a vector coordinate X pointing in a direction from inlet 402 to outlet 403. Component 450 may comprise a substrate 152 or a semiconductor module 150. Furthermore, component 450 may comprise a power semiconductor module.

Note that semiconductor modules like semiconductor module 150 or component 450 may comprise a base plate. In this case, cold plates 200 and 400 may be coupled to a main face of the base plate such that at least a part of the main face acts as the “missing” top cover of channels 201 and 401 as described above.

FIG. 4B shows a perspective view of the bottom side of cold plate 400. Channel 401 sticks out of a cold plate plane bottom side 407 resulting in a height difference d between cold plate plane bottom side 407 and channel outer bottom surface area 404B. Height difference d is depicted in the cut view of FIG. 2A. Height difference d may in particular be identical to channel depth D.

Height difference d may be a result of a fabrication process of cold plates like cold plates 200 and 400, wherein the fabrication process comprises one or more of stamping, rolling and pressing a metal plate in order to fabricate channels like channels 201 and 401. Furthermore, such a fabrication process may result in channels 201, 401 comprising S-shaped vertical channel side walls 208, 408 as shown in FIGS. 2A, 2B, 4A and 4B.

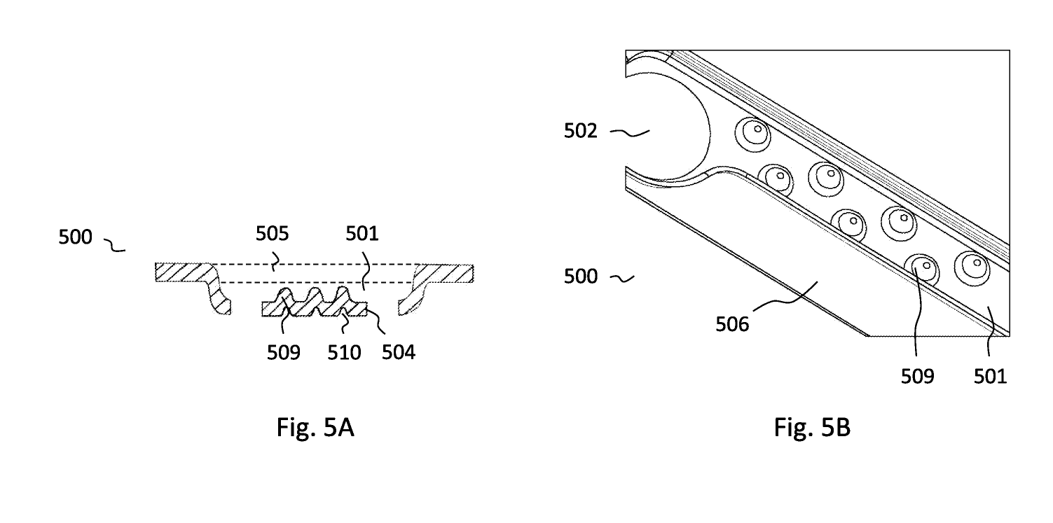

FIG. 5A shows an example of a cold plate 500 comprising a channel 501, wherein channel 501 comprises structures 509 configured to create turbulences in a cooling fluid flowing through channel 501. Such turbulences may improve a heat uptake capacity (or thermal absorption rate) of a cooling fluid flowing through channel 501. The structures 509 of cold plate 500 take the form of dimples extending into channel 501 from its bottom. The structures 509 are arranged in channel bottom part 504.

Structures 509 may be fabricated in the same fabrication step(s) as channel 501. In particular, structures 509 may be fabricated in the same stamping, rolling or pressing treatment as channel 501. Structures 509 may have a hollow core 510 on the outside of cold plate 500 which may result from the stamping, rolling or pressing treatment.

FIG. 5B shows a zoomed in perspective view of a part of channel 501. Structures 509 may have any desirable shape, in particular structures 509 may have a round outline and may further have a dome shaped top. Structures 509 may have any desirable height measured from the bottom of channel 501. The height of structures 509 may range from almost zero to a height that equals the channel depth D. Therefore, the top of structures 509 may touch or almost touch a second main surface of a substrate coupled to the cold plate 500 and acting as channel top cover.

Structures 509 may be arranged in any suitable manner inside the channel 501, for example in one or more rows and/or laterally displaced. Furthermore, any desirable number of structures 509 may be used.

Alternatively or additionally to the structures 509, a second main surface of a substrate coupled to the cold plate and acting as channel top cover may comprise structures reaching into the channel. These structures may serve the same function as structures 509. An example of such structures maybe so called “Pin Fins”.

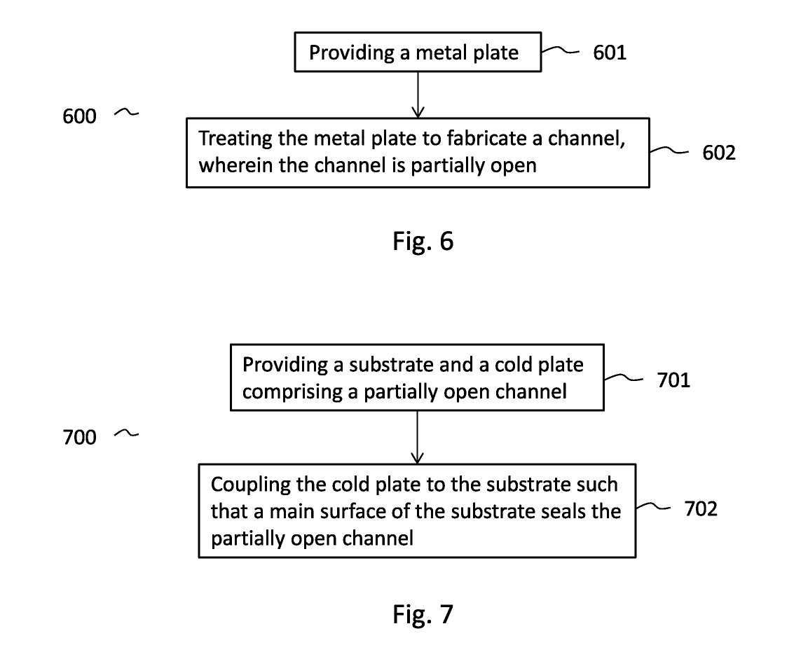

FIG. 6 shows a flow diagram of a method 600 for fabricating a cold plate. Method 600 comprises a first method step 601, wherein first method step 601 comprises providing a metal plate. Method 600 further comprises a second method step 602, wherein second method step 602 comprises treating the metal plate to fabricate a channel, wherein the channel is partially open. In one example, treating the metal plate may comprise one or more of stamping, rolling and pressing the metal plate.

FIG. 7 shows a flow diagram of a method 700 for fabricating a device comprising a substrate and a cold plate. The substrate may be configured to have at least a first semiconductor chip coupled to the substrate. Method 700 comprises a first method step 701, wherein first method step 701 comprises providing a substrate and a cold plate comprising a partially open channel. Method 700 further comprises a second method step 702, wherein second method step 702 comprises coupling the cold plate to the substrate such that a main surface of the substrate seals the partially open channel.

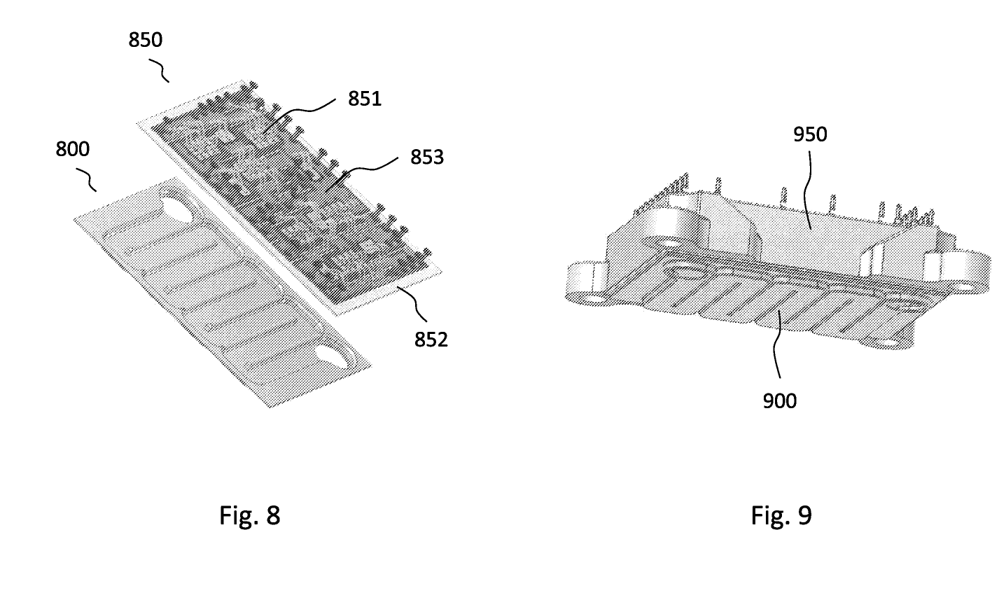

FIG. 8 shows a substrate 850 and a cold plate 800, wherein cold plate 800 is configured to be coupled to substrate 850 in order to fabricate a semiconductor device. Fabrication of cold plate 800 and coupling of cold plate 800 to substrate 850 can be performed as described with respect to FIGS. 1A-7. Substrate 850 may comprise an aluminum layer 852, a copper layer 853, wherein copper layer 853 may comprise defined structures and at least one semiconductor chip 851. Semiconductor chip 851 may be electrically coupled to copper layer 853 via bond wires.

FIG. 9 shows an example of a semiconductor device 90, wherein semiconductor device 90 comprises a substrate 950 and a cold plate 900 coupled to substrate 950. Semiconductor device 90 may be fabricated as described with respect to FIGS. 1A-8. Substrate 950 maybe an example of a power semiconductor substrate.

Although the present invention and its advantages have been described in detail, it should be understood that various changes, substitutions and alterations can be made herein without departing from the spirit and concept of the disclosure as defined by the appended claims.

It is possible to combine features of the disclosed devices and methods unless specifically stated otherwise.

Moreover, the concept of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their concept such processes, machines, manufacture, compositions of matter, means, methods, or steps.

What is claimed is:

1. A device, comprising:
a semiconductor module; and
a cold plate comprised of a single piece member.

2. The device of claim 1, wherein the cold plate comprises a channel.

3. The device of claim 2, wherein a main face of the semiconductor module forms a top part of an inner surface of the channel.

4. The device of claim 1, wherein the semiconductor module is a power semiconductor module.

5. The device of claim 1, wherein the cold plate is coupled to the semiconductor module via one or more of a sintering bond, a solder bond, a welded joint, and an active metal brazing bond.

6. The device of claim 1, wherein the cold plate comprises one or more of aluminum, an aluminum alloy, copper, and a copper alloy.

7. The device of claim 3, wherein the semiconductor module comprises a base plate, and wherein the main face of the semiconductor module forming the top part of the inner surface of the channel is a main face of the base plate.

8. The device of claim 3, wherein the semiconductor module comprises a substrate comprising a stack of more than one material layers, and wherein the main face of the semiconductor module forming the top part of the inner surface of the channel comprises an outer layer of the stack.

9. The device of claim 1, wherein the single piece member comprises one or more of a stamped metal plate, a rolled metal plate, and a pressed metal plate.

10. The device of claim 2, wherein the channel comprises structures configured to cause turbulences in a cooling fluid flowing through the channel.

11. The device of claim 10, wherein a main face of the semiconductor module forms a top part of an inner surface of the channel, and wherein the structures are arranged in a bottom part of the inner surface of the channel, opposite the top part.

12. The device of claim 2, wherein the channel has a meandering shape.

13. A cold plate, comprising:
a channel,
wherein the cold plate is comprised of a single piece member, and
wherein a top side of the channel is open, and wherein a bottom side of the channel opposite the top side comprises an inlet and an outlet.

14. The cold plate of claim 13, wherein the channel comprises S-shaped side walls.

15. The cold plate of claim 13, wherein a depth of the channel is between 1 mm and 6 mm.

16. A method for fabricating a device, the method comprising:
providing a substrate configured for coupling a semiconductor chip to the substrate;
providing a cold plate comprising a channel; and
coupling the cold plate to the substrate,
wherein the cold plate is comprised of a single piece member.

17. The method of claim 16, wherein coupling the cold plate to the substrate comprises one or more of sintering, soldering, welding, and active metal brazing.

18. The method of claim 16, wherein coupling the cold plate to the substrate is performed such that no thermal grease layer is arranged between the semiconductor module and the cold plate.

19. The method of claim 16, wherein the channel comprises an open top side, and wherein coupling the cold plate to the substrate comprises sealing the open top side of the channel with a main surface of the substrate.

20. The method of claim 16, wherein the substrate is a Direct Copper Bond substrate, or a Direct Aluminum Bond substrate, or a Direct Copper Aluminum Bond substrate, or an Active Metal Braze substrate.
